(19) United States
(12) Patent Application Publication
(10) Pub. No.: US 2025/0057001 A1
(43) Pub. Date: Feb. 13, 2025

(54) DISPLAY DEVICE

(71) Applicant: Japan Display Inc., Tokyo (JP)

(72) Inventors: Junko NAGASAWA, Tokyo (JP); Yuji MAEDE, Tokyo (JP)

(21) Appl. No.: 18/786,863

(22) Filed: Jul. 29, 2024

(30) Foreign Application Priority Data
Aug. 10, 2023 (JP) 2023-131127

(51) Int. Cl. H10K 59/38; H10K 59/122; H10K 59/80; H10K 102/00

(52) U.S. Cl. CPC H10K 59/38; H10K 59/122; H10K 59/8722; H10K 59/8791; H10K 2102/3026

(57) ABSTRACT

According to one embodiment, a display device includes a plurality of pixels, an insulating substrate, an organic electroluminescent element, a sealing layer, color filter layers located on the sealing layer and including a first color filter of a first color, a second color filter of a second color, and a third color filter of a third color, a first pixel aperture where the first color filter is located, a second pixel aperture where the second color filter is located, and a third pixel aperture where the third color filter is located, in each of pixels, and a light-shielding area surrounding each of the first to third pixel apertures, in which the first to third color filters are stacked one on another.

### CROSS-REFERENCE TO RELATED APPLICATIONS

This application is based upon and claims the benefit of priority from Japanese Patent Application No. 2023-131127, filed Aug. 10, 2023, the entire contents of which are incorporated herein by reference.

### FIELD

Embodiments described herein relate generally to a display device.

### BACKGROUND

In recent years, organic EL element OLED display devices that in which organic light emitting diodes (OLEDs) are applied as display elements have been put to practical use. Organic electroluminescent (EL) display devices comprise a sealing layer that seals the OLED. In such organic EL element OLED displays, a configuration in which a color filter layer is formed on the sealing layer without a polarizer is known.

Further, a color filter forming substrate is known in which light shielding layers and spacers are formed by overlapping color filter layers of colors for forming red, green, and blue pixels.

### BRIEF DESCRIPTION OF THE DRAWINGS

FIG. 1 is a plan view schematically showing a display device according to an embodiment.

FIG. 2 is a cross-sectional view showing a display area of the display device shown in FIG. 1.

FIG. 3 shows plan views each showing layout of color filter layers arranged in one pixel.

FIG. 4 is a plan views showing layout of light-shielding areas of one pixel.

FIG. 5 is a cross-sectional view showing the display panel taken along line A-B shown in FIG. 4.

FIG. 6 is a cross-sectional view showing the display panel taken along line C-D shown in FIG. 4.

FIG. 7 is a cross-sectional view showing the display panel taken along line E-F shown in FIG. 4.

FIG. 8 is a plan view showing layout of the light-shielding areas and groove portions of one pixel.

FIG. 9 is a cross-sectional view showing the display panel taken along line A-B shown in FIG. 8.

FIG. 10 is a cross-sectional view showing the display panel taken along line C-D shown in FIG. 8.

FIG. 11 is a cross-sectional view showing the display panel taken along line E-F shown in FIG. 8.

### DETAILED DESCRIPTION

In general, according to one embodiment, a display device comprises: a plurality of pixels, an insulating substrate, an organic electroluminescent element located on the insulating substrate and including an organic light emitting layer, a sealing layer sealing the organic electroluminescent element, color filter layers located on the sealing layer and including a first color filter of a first color, a second color filter of a second color different from the first color, and a third color filter of a third color different from the first color and the second color, a first pixel aperture where the first color filter is located, a second pixel aperture where the second color filter is located, and a third pixel aperture where the third color filter is located, in each of the plurality of pixels and a light-shielding area surrounding each of the first pixel aperture, the second pixel aperture, and the third pixel aperture, and the first color filter, the second color filter, and the third color filter are stacked one on another.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

### First Embodiment

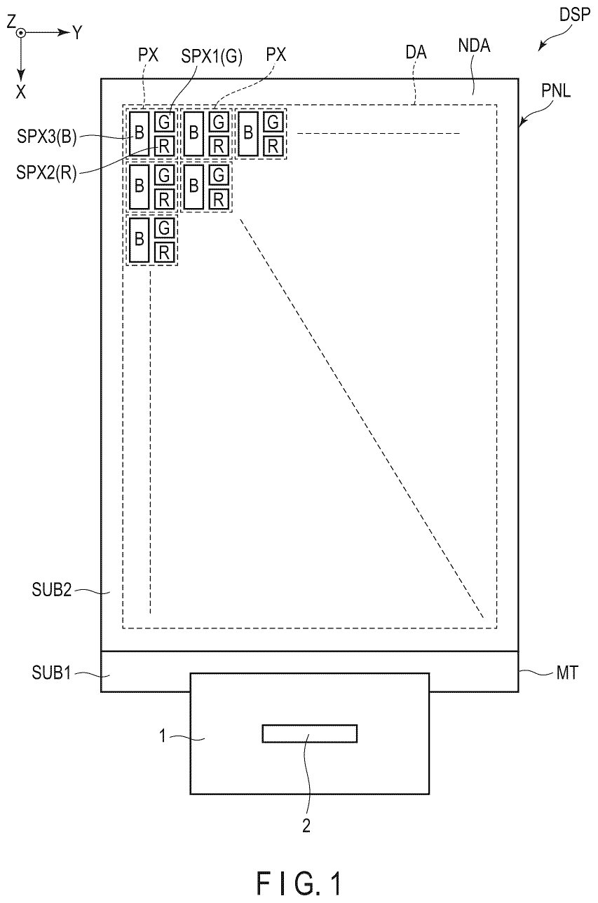

First, a configuration of the first embodiment will be described with reference to FIGS. 1 to 7.

For example, a first direction X, a second direction Y and a third direction Z are orthogonal to each other, but may intersect at an angle other than 90 degrees. The first direction X and the second direction Y correspond to directions parallel to a main surface of a substrate that constitutes the display device DSP. The third direction Z corresponds to a thickness direction of the display device DSP. In this specification, the direction toward the tip of the arrow in the third direction z is defined as up or above, and the direction opposite to the direction toward the tip of the arrow in the third direction z is defined as down or below. Further, it is assumed that there is an observation position to observe the optical control element on a tip side of the arrow in the third direction Z. Here, viewing from this observation position toward the X-Y plane defined by the first direction X and the second direction Y is referred to as plan view.

The display device DSP comprises a display panel PNL and a wiring substrate 1 mounted on the display panel PNL.

The display panel PNL is an organic EL element OLED display panel and comprises a first substrate SUB1 and a second substrate SUB2 disposed to oppose the first substrate SUB1. The first substrate SUB1 includes a mount portion MT exposed to an outer side from the second substrate SUB2. The display panel PNL comprises a display area DA which displays images and a non-display area NDA which surrounds the display area DA. The display panel PNL comprises a plurality of pixels PX arranged in a matrix along the first direction X and the second direction Y in the display area DA.

The pixels PX are each constituted by a subpixel SPX1 that displays green color (G), a subpixel SPX2 that displays color red (R), and a subpixel SPX3 that displays blue color (B). In each pixel PX, the subpixel SPX3 extends along the first direction X. The subpixel SPX1 is aligned with the subpixel SPX3 along the second direction Y. The subpixel SPX2 is aligned with the subpixel SPX3 along the second direction Y and also aligned with the subpixel SPX1 along the first direction X.

Note that the size, arrangement, and color of each subpixel are not limited to those of the example illustrated here. Further, in the example illustrated, the pixels PX having the identical subpixel pattern are aligned in a matrix, but the configuration is not limited to this. The size, arrangement, and color of subpixels may be different from one pixel PX to another.

The wiring substrate 1 is a flexible substrate and is mounted on the mount portion MT. The display panel PNL and the wiring substrate 1 are electrically connected to each other. The wiring substrate 1 comprises a drive IC chip 2 that drives the display panel PNL. Note that the drive IC chip 2 may be mounted on the mount portion MT.

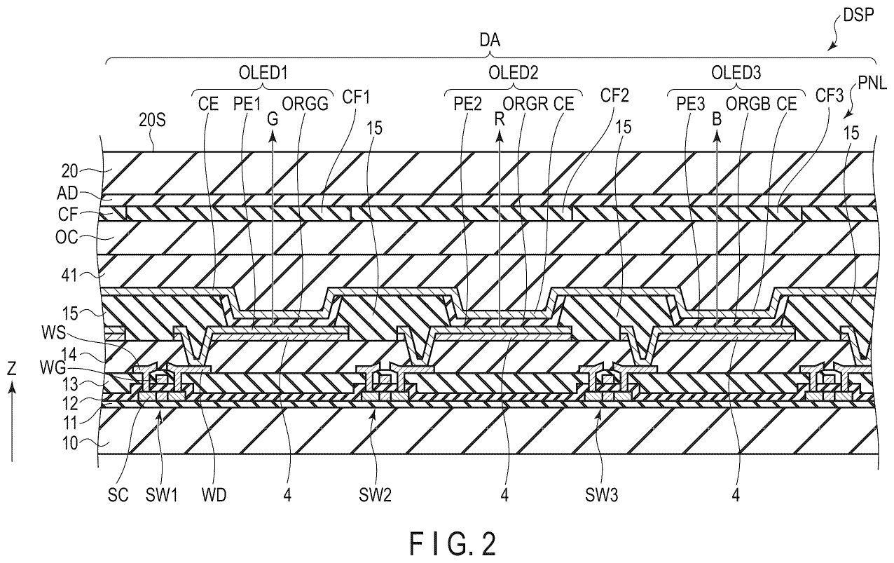

FIG. 2 is a cross-sectional view showing the display area DA of the display device DSP shown in FIG. 1.

As shown in FIG. 2, the display panel PNL comprises an insulating substrate 10, switching elements SW1, SW2, and SW3, a reflective layer 4, organic EL elements OLED1, OLED2, and OLED3, a sealing layer 41, an overcoat layer OC, color filter layers CF, an adhesive layer AD, a sealing substrate 20 and the like.

The insulating substrate 10 may be a glass substrate or a flexible resin film. The first insulating film 11 covers the insulating substrate 10.

The switching elements SW1, SW2, and SW3 are formed on the first insulating film 11. In the example illustrated, the switching elements SW1, SW2, and SW3 are each constituted by a top-gate thin-film transistor, but they may as well be constituted by a bottom-gate thin-film transistor. Since the switching elements SW1, SW2, and SW3 have the same configuration, their configuration will now be explained in more detail while focusing on the switching element SW1. The switching element SW1 comprises a semiconductor layer SC formed on the first insulating film 11. The semiconductor layer SC is covered by the second insulating film 12. Further, the second insulating film 12 is disposed over the first insulating film 11 as well.

The gate electrode WG of the switching element SW1 is formed on the second insulating film 12 and is located directly above the semiconductor layer SC. The gate electrode WG is covered by the third insulating film 13. Further, the third insulating film 13 is disposed over the second insulating film 12 as well.

The first insulating film 11, the second insulating film 12, and the third insulating film 13 configured as described above are, for example, inorganic insulating films each formed from an inorganic material such as silicon oxide or silicon nitride.

The source electrode WS and drain electrode WD of the switching element SW1 are formed on the third insulating film 13. The source electrode WS and the drain electrode WD are electrically connected to the semiconductor layer SC via contact holes that penetrate the second insulating film 12 and the third insulating film 13, respectively. The switching element SW1 is covered by the fourth insulating film 14. The fourth insulating film 14 is disposed over the third insulating film 13 as well. The fourth insulating film 14 configured as described above is formed, for example, by an organic material such as a transparent resin.

The reflective layer 4 is formed on the fourth insulating film 14. The reflective layer 4 is formed of a metal material with high light reflectivity, such as aluminum or silver. The upper surface of the reflective layer 4 may be a flat surface or an uneven surface to impart light scattering properties.

The organic EL elements OLED1 to OLED3 are formed on the fourth insulating film 14. In other words, the organic EL elements OLED1 to OLED3 are located on the insulating substrate 10. In the example illustrated, the organic EL element OLED1 is electrically connected to the switching element SW1, the organic EL element OLED2 is electrically connected to the switching element SW2, and the organic EL element OLED3 is electrically connected to the switching element SW3. The organic EL elements OLED1 to OLED3 are configured as a top emission type, and emit green light, red light, and blue light toward a sealing substrate 20 side, respectively. All of these organic EL elements OLED1 to OLED3 have the same configuration. In the example illustrated, the organic EL elements OLED1 to OLED3 are each compartmentalized by a rib 15.

The organic EL element OLED1 comprises a pixel electrode PE1 formed on the reflective layer 4. The pixel electrode PE1 is brought into contact with the drain electrode WD of the switching element SW1 and is electrically connected to the switching element SW1. Similarly, the organic EL element OLED2 comprises a pixel electrode PE2 electrically connected to the switching element SW2, and the organic EL element OLED3 comprises a pixel electrode PE3 electrically connected to the switching element SW3. The pixel electrodes PE1, PE2, and PE3 are each formed, for example, from a transparent conductive material such as indium tin oxide (ITO) or indium zinc oxide (IZO).

For example, the organic EL element OLED1 comprises an organic light emitting layer ORGG which emits light in green, the organic EL element OLED2 comprises an organic light emitting layer ORGR that emits light in red, and the organic EL element OLED3 has an organic light emitting layer ORGB that emits light in blue. The organic light emitting layer ORG is located above the pixel electrode PE1, the organic light emitting layer ORGR is located above the pixel electrode PE2, and the organic light emitting layer ORGB is located above the pixel electrode PE3.

The organic EL elements OLED1 to OLED3 comprise a common electrode CE. The common electrode CE is located above the organic light emitting layers ORG, ORGR, and ORGB. The common electrode CE is located above the rib 15 as well. Of each pixel electrode PE and the common electrode CE, one is an anode and the other is a cathode. The common electrode CE is formed, for example, of an MgAg alloy.

The sealing layer 41 seals the organic EL elements OLED1, OLED2, and OLED3. Further, the sealing layer 41 seals the members disposed between the insulating substrate 10 and itself, as well. The sealing layer 41 inhibits oxygen and moisture from entering the organic EL elements OLED1, OLED2, and OLED3, and suppresses degradation of the organic EL elements OLED1, OLED2, and OLED3. For example, the sealing layer 41 is constituted by a stacked body of an inorganic film, an organic film, and an inorganic film. The inorganic films that constitute the sealing layer 41 are formed of, for example, silicon nitride.

The overcoat layer OC covers the sealing layer 41. The overcoat layer OC is located between the sealing layer 41 and the color filter layers CF. The overcoat layer OC is formed, for example, from an organic material such as a transparent resin.

The color filter layers CF cover the overcoat layer OC. In other words, the color filter layers CF are located on the sealing layer 41. The color filter layers CF include a first color filter CF1 of a first color, a second color filter CF2 of a second color different from the first color, and a third color filter CF3 of a third color different from the first and second colors.

The first color first color filter CF1 is, for example, a green color filter. The second color second color filter CF2 is, for example, a red color filter. The third color filter CF3 is, for example, a blue color filter.

The first color filter CF1 overlaps the organic EL element OLED1 that emits green light. The second color filter CF2 overlaps the organic EL element OLED2 that emits red light. The third color filter CF3 overlaps the organic EL element OLED3 that emits blue light.

The colors of the first color filter CF1, the second color filter CF2, and the third color filter CF3 are not limited to those of the example provided above but can be changed as appropriate according to the emitting colors of the organic EL elements OLED1 to OLED3.

The sealing substrate 20 is located above the color filter layers CF and is bonded to the color filter layers CF using an adhesive layer AD. In other words, the adhesive layer AD is located between the color filter layers CF and the sealing substrate 20. The sealing substrate 20 may be a glass substrate or a flexible resin film.

The sealing substrate 20 includes a display surface 20S on an opposite side to the surface in contact with the adhesive layer AD. That is, the display panel PNL includes a display surface 20S on an opposite side to the insulating substrate 10 with respect to the organic EL elements OLED1, OLED2, and OLED3.

In the display device DSP configured as such, when the organic EL elements OLED1 to OLED3 each emit light, the organic EL element OLED1 emits green light, the organic EL element OLED2 emits red light, and the organic EL element OLED3 emits blue light. Therefore, the color display of the display device DSP is realized.

The pixels PX shown in FIG. 1 are each, for example, a minimum unit that constitutes a color image and comprise the above-described organic EL elements OLED1 to OLED3. More specifically, the subpixel SPX1 comprises the organic EL element OLED1, the subpixel SPX2 comprises the organic EL element OLED2, and the subpixel SPX3 comprises the organic EL element OLED3.

In the configuration example provided above, the organic EL elements OLED1 to OLED3 comprise an organic light emitting layer ORG that emits green light, an organic light emitting layer ORGR that emits red light, and an organic light emitting layer ORGB that emits blue light, respectively, but the configuration is not limited to this. The organic EL elements OLED1 to OLED3 may comprise a common organic light emitting layer. In this case, for example, the organic EL elements OLED1 to OLED3 emit white light. In this embodiment, since the display panel PNL comprises color filter layers CF, the color display of the display device DSP can be realized even when the organic EL elements OLED1 to OLED3 emit white light.

Moreover, the display panel PNL of this embodiment does not comprise a polarizer on the sealing substrate 20, but in place, the color filter layer CF is disposed on the sealing layer 41. Therefore, the color filter layer CF can suppress the reflection of external light at the common electrode CE and the reflection layer 4. Thus, as compared with the case where a polarizer is used to suppress the reflection of external light, the transmittance of light emitted from the organic EL elements OLED1 to OLED3 can be improved. Thus, the lowering of display brightness can be suppressed and power consumption can be reduced. Further, since the color filter layers CF are thinner as compared to the polarizer, the display panel PNL can be made thinner. Furthermore, the cost required when using a polarizer can be reduced.

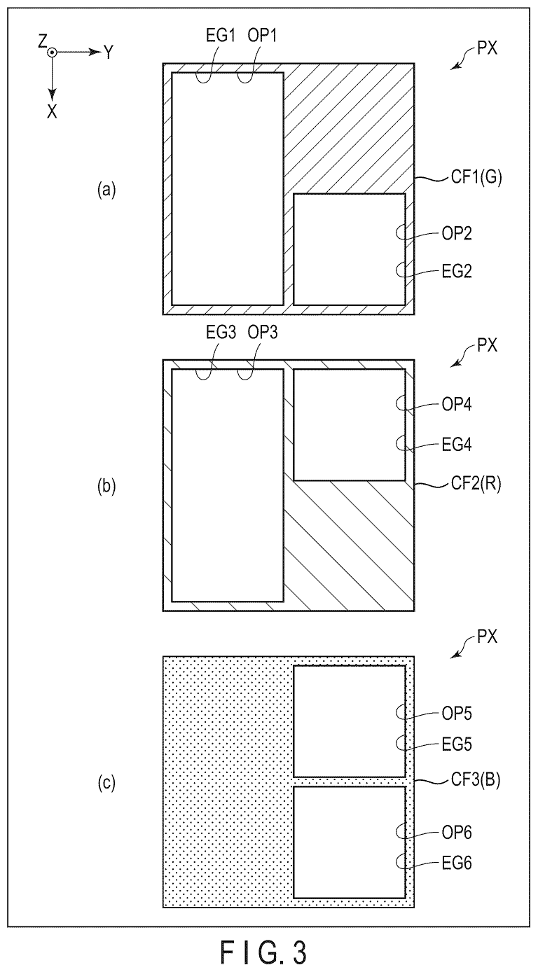

FIG. 3 shows plan views each showing the layout of the color filter layers CF arranged in one pixel PX.

In FIG. 3, part (a) is a plan view showing the layout of the first color filter CF1 disposed in one pixel PX. FIG. 3, part (b) is a plan view showing the layout of the second color filter CF2 disposed in one pixel PX. FIG. 3, part (c) is a plan view showing the layout of the third color filter CF3 disposed in one pixel PX.

As shown in FIG. 3, part (a), the first color filter CF1 includes a first aperture OP1 and a second aperture OP2. The first aperture OP1 and the second aperture OP2 are aligned along the second direction Y. The first color filter CF1 has a first inner edge EG1 opposing the first aperture OP1 and a second inner edge EG2 opposing the second aperture OP2.

As shown in FIG. 3, part (b), the second color filter CF2 includes a third aperture OP3 and a fourth aperture OP4. The third aperture OP3 and the fourth aperture OP4 are aligned along the second direction Y. The second color filter CF2 includes a third inner edge EG3 opposing the third aperture OP3 and a fourth inner edge EG4 opposing the fourth aperture OP4.

As shown in FIG. 3, part (c), the third color filter CF3 includes a fifth aperture OP5 and a sixth aperture OP6. The fifth aperture OP5 and the sixth aperture OP6 are aligned along the first direction X. The third color filter CF3 includes a fifth inner edge EG5 opposing the fifth aperture OP5 and a sixth inner edge EG6 opposing the sixth aperture OP6.

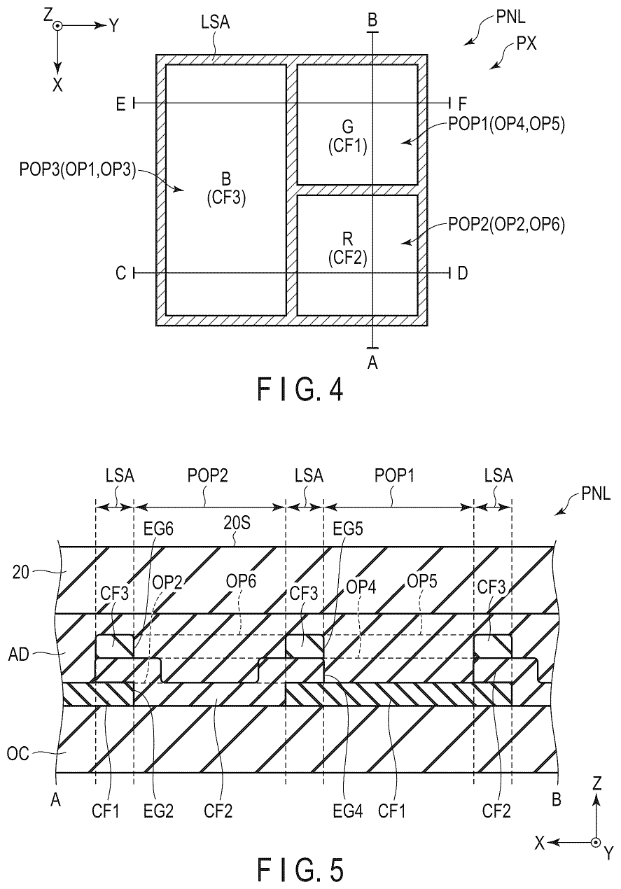

FIG. 4 is a plan view showing the layout of the light-shielding area LSA of one pixel PX. The configuration shown in FIG. 4 corresponds to the configuration in which the first color filter CF1, the second color filter CF2, and the third color filter CF3 overlap each other along the third direction Z as shown in FIG. 3.

The display panel PNL includes, in each pixel PX, a first pixel aperture POP1 where the first color filter CF1 is located, a second pixel aperture POP2 where the second color filter CF2 is located, and a third pixel aperture POP3 where the third color filter CF3 is located. The first pixel aperture POP1, the second pixel aperture POP2, and the third pixel aperture POP3 correspond to regions through which light emitted from the organic EL elements OLED1 to OLED3 passes, respectively.

In terms of all the pixels, the third pixel apertures POP3 extend along the first direction X. The first pixel apertures POP1 are aligned along the second direction Y in which the third pixel apertures POP3 are arranged. The second pixel apertures POP2 are aligned along the second direction Y in which the third pixel apertures POP3 are arranged and further along the first direction X in which the first pixel apertures POP1 are arranged.

In each pixel, the first pixel aperture POP1 overlaps the fourth aperture OP4 of the second color filter CF2 and the fifth aperture OP5 of the third color filter CF3. The second pixel aperture POP2 overlaps the second aperture OP2 of the first color filter CF1 and the sixth aperture OP6 of the third color filter CF3. The third pixel aperture POP3 overlaps the first aperture OP1 of the first color filter CF1 and the third aperture OP3 of the second color filter CF2.

The display panel PNL includes a light-shielding area LSA that surrounds each of the first pixel aperture POP1, the second pixel aperture POP2, and the third pixel aperture POP3. The light-shading area LSA is constituted by the first color filter CF1, the second color filter CF2, and the third color filter CF3 stacked on top of each other, as will be described later. The light-shielding area LSA corresponds to a region that shields light emitted from the organic EL elements OLED1 to OLED3.

FIG. 5 is a cross-sectional view of the display panel PNL taken along line A-B shown in FIG. 4. FIG. 5 illustrates the configuration of the layers above the overcoat layer OC.

The first color filter CF1, the second color filter CF2, and the third color filter CF3 are stacked on top of each other along the third direction z in the light-shielding area LSA. In other words, the first color filter CF1, the second color filter CF2, and the third color filter CF3 are stacked one on another in the light-shielding area LSA from an insulating substrate 10 side to a display surface 20S side. More specifically, in the light-shielding area LSA, the first color filter CF1 is in contact with the overcoat layer OC, the second color filter CF2 is located on the first color filter CF1, and the third color filter CF3 is located on the second color filter CF2.

In the first pixel aperture POP1, the first color filter CF1 is in contact with the overcoat layer OC. In the second pixel aperture POP2, the second color filter CF2 is in contact with the overcoat layer OC. In the second pixel aperture POP2, the second color filter CF2 is located inside the second aperture OP2.

The second inner edge EG2 of the first color filter CF1 is covered by the second color filter CF2. The fourth inner edge EG4 of the second color filter CF2, the fifth inner edge EG5 and the sixth inner edge EG6 of the third color filter CF3 are in contact with the adhesive layer AD.

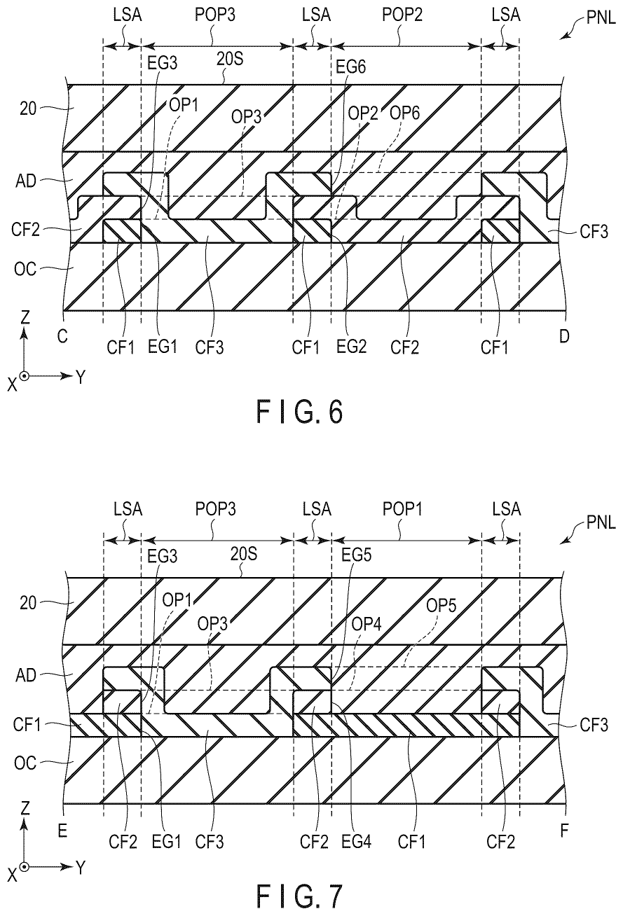

FIG. 6 is a cross-sectional view of the display panel PNL taken along line C-D shown in FIG. 4.

The first color filter CF1, the second color filter CF2, and the third color filter CF3 are stacked one on another in the light-shielding area LSA from the insulating substrate 10 side to the display surface 20S side.

In the third pixel aperture POP3, the third color filter CF3 is in contact with the overcoat layer OC. In the third pixel aperture POP3, the third color filter CF3 is located inside the first aperture OP1.

The first inner edge EG1 of the first color filter CF1 is covered by the third color filter CF3. The second inner edge EG2 of the first color filter CF1 is covered by the second color filter CF2. The third inner edge EG3 of the second color filter CF2 is covered by the third color filter CF3. The sixth inner edge EG6 of the third color filter CF3 is brought into contact with the adhesive layer AD.

FIG. 7 is a cross-sectional view of the display panel PNL taken along line E-F shown in FIG. 4.

The first color filter CF1, the second color filter CF2, and the third color filter CF3 are stacked one on another in the light-shielding area LSA from the insulating substrate 10 side to the display surface 20S side.

The first inner edge EG1 of the first color filter CF1 is covered by the third color filter CF3. The third inner edge EG3 of the second color filter CF2 is covered by the third color filter CF3. The fourth inner edge EG4 of the second color filter CF2 and the fifth inner edge EG5 of the third color filter CF3 are brought into contact with the adhesive layer AD.

The display panel PNL of this embodiment does not comprise a light-shielding layer in the display area DA. For example, when an organic electroluminescent display device has a light-shielding layer, the light-shielding layer is formed by curing at low temperature. Here, as a result, in the process of forming the color filter layer CF after the light-shading layer is formed, the uncured portions of the light-shading layer may react during the development of the color filter layer CF, which may result in thinning of the film of the light-shading layer. Particularly, in the step of forming the first color filter CF1 of the first color during the process of forming the color filter layers CF, the thinning of the film of the light-shielding layer is likely to occur. In order to suppress the film thinning of the light-shielding layer, the light-shielding layer is subjected to a post-exposure process. But a high amount of exposure may result in a heavy load in manufacturing.

According to this embodiment, the light-shielding area LSA is formed by stacking the first color filter CF1, the second color filter CF2, and the third color filter CF3 one on another. With this configuration, the occurrence of the film thinning of the light-shielding layer described above can be suppressed, and the load on the manufacturing while forming the light-shielding layer can be eliminated. Further, it is possible to reduce the cost of forming the light-shielding layer.

### Second Embodiment

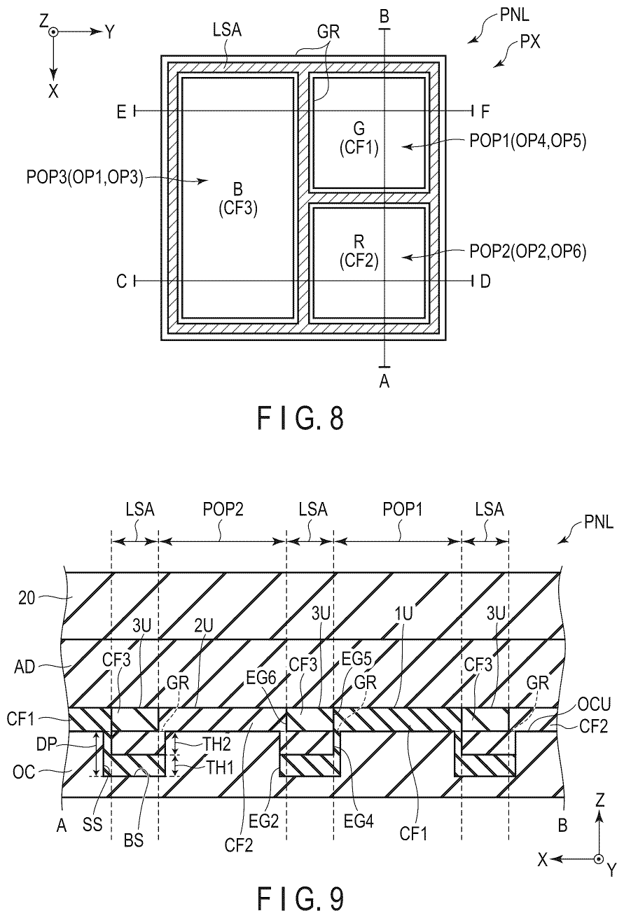

Next, the configuration of the second embodiment will be described with reference to FIGS. 8 to 11.

FIG. 8 is a plan view showing the layout of the light-shielding area LSA and groove portions GR of one pixel PX. The configuration shown in FIG. 8 is different from the configuration shown in FIG. 4 in that the display panel PNL includes groove portions GR.

The groove portions GR overlap the light-shielding area LSA. The groove portions GR surround each of the first pixel aperture POP1, the second pixel aperture POP2, and the third pixel aperture POP3.

FIG. 9 is a cross-sectional view of the display panel PNL taken along line A-B shown in FIG. 8. The configuration shown in FIG. 9 is different from the configuration shown in FIG. 5 in that the overcoat layer OC includes groove portions GR.

The overcoat layer OC includes groove portions GR at locations overlapping the light-shielding area LSA. The groove portions GR are formed on an upper surface OCU of the overcoat layer OC. The first color filter CF1, the second color filter CF2, and the third color filter CF3 are stacked on each other at positions overlapping the groove portions GR, respectively. A part of the first color filter CF1 is located inside the respective groove portion GR. Further, a part of the second color filter CF2 is located inside the respective groove portion GR.

The upper surface 10 of the first color filter CF1 in the first pixel aperture POP1, the upper surface 20 of the second color filter CF2 in the second pixel aperture POP2, and the upper surface 30 of the third color filter CF3 in the light-shielding area LSA are located on substantially the same plane.

The groove portions GR have a depth DP, for example, approximately equivalent to the sum of a film thickness TH1 of the first color filter CF1 and a film thickness TH2 of the second color filter CF2.

The second inner edge EG2 of the first color filter CF1 is in contact with the overcoat layer OC inside the respective groove portion GR. The fourth inner edge EG4 of the second color filter CF2 is in contact with the first color filter CF1. The fifth inner edge EG5 of the third color filter CF3 is in contact with the first color filter CF1. The sixth inner edge EG6 of the third color filter CF3 is in contact with the second color filter CF2.

According to the second embodiment, the overcoat layer OC includes groove portions GR. With this configuration, steps made by the color filter layers CF in the light-shading area LSA can be reduced. Therefore, undesired diffusive reflection of light due to the steps of the color filter layers CF can be suppressed.

Further, the groove portions GR each include a bottom surface BS and side surfaces SS rising from the bottom surface BS. The angle made between the bottom surface BS and the respective side surface SS inside the groove portions GR is about 90 degrees. Here, when the groove portions GR are formed to be steeply tapered, the steps made by the color filter layers CF in the light-shielding area LSA can be further reduced.

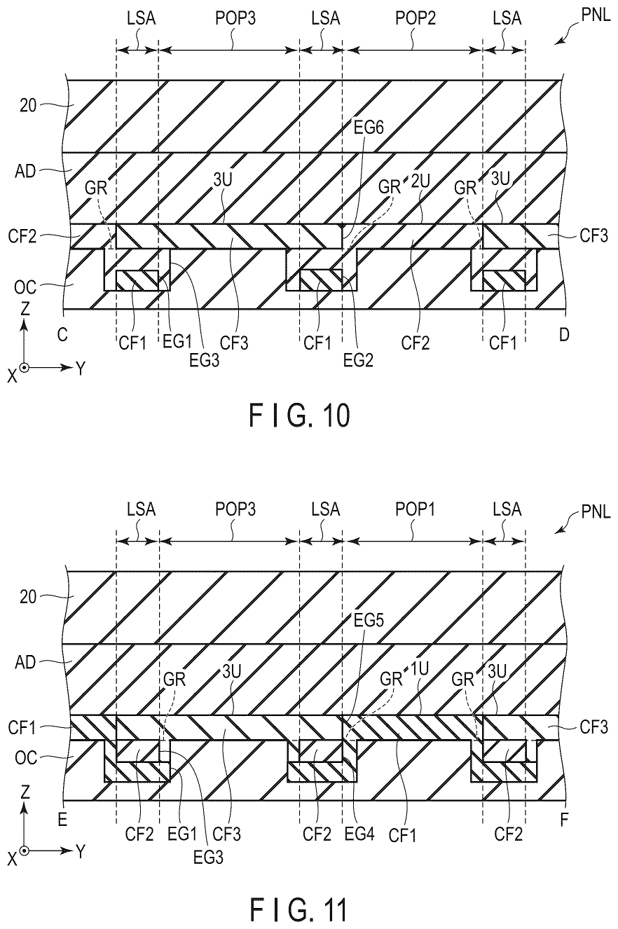

FIG. 10 is a cross-sectional view of the display panel PNL taken along line C-D shown in FIG. 8. The configuration shown in FIG. 10 is different from the configuration shown in FIG. 6 in that the overcoat layer OC includes groove portions GR.

A part of the first color filter CF1 is located inside the respective groove portion GR. Further, a part of the second color filter CF2 is located inside the respective groove portion GR.

The upper surface 20 of the second color filter CF2 in the second pixel aperture POP2 and the upper surface 30 of the third color filter CF3 in the third pixel aperture POP3 and the light-shielding area LSA are located on substantially the same plane.

The first inner edge EG1 of the first color filter CF1 is in contact with the second color filter CF2. The second inner edge EG2 of the first color filter CF1 is in contact with the second color filter CF2. The third inner edge EG3 of the second color filter CF2 is in contact with the overcoat layer OC inside the respective groove portion GR. The sixth inner edge EG6 of the third color filter CF3 is in contact with the second color filter CF2.

FIG. 11 is a cross-sectional view of the display panel PNL taken along line E-F shown in FIG. 8. The configuration shown in FIG. 11 is different from the configuration shown in FIG. 7 in that the overcoat layer OC includes groove portions GR.

A part of the first color filter CF1 is located inside the respective groove portion GR. Further, a part of the second color filter CF2 is located inside the respective groove portion GR.

The upper surface 10 of the first color filter CF1 in the first pixel aperture POP1, the upper surface 30 of the third color filter CF3 in the third pixel aperture POP3 and the upper surface 30 of the third color filter CF3 in the light-shielding area LSA are located on substantially the same plane.

The first inner edge EG1 of the first color filter CF1 is in contact with the overcoat layer OC inside the respective groove portion GR. The third inner edge EG3 of the second color filter CF2 is in contact with the third color filter CF3. The fourth inner edge EG4 of the second color filter CF2 is in contact with the first color filter CF1. The fifth inner edge EG5 of the third color filter CF3 is in contact with the first color filter CF1.

As explained above, according to this embodiment, it is possible to obtain a display device that can reduce the load on its manufacture and the cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels;
an insulating substrate;
an organic electroluminescent element located on the insulating substrate and including an organic light emitting layer;
a sealing layer sealing the organic electroluminescent element;
color filter layers located on the sealing layer and including a first color filter of a first color, a second color filter of a second color different from the first color, and a third color filter of a third color different from the first color and the second color;
a first pixel aperture where the first color filter is located, a second pixel aperture where the second color filter is located, and a third pixel aperture where the third color filter is located, in each of the plurality of pixels; and
a light-shielding area surrounding each of the first pixel aperture, the second pixel aperture, and the third pixel aperture, in which the first color filter, the second color filter, and the third color filter are stacked one on another.

2. The display device of claim 1, further comprising:
a display surface on an opposite side to the insulating substrate with respect to the organic electroluminescent element,
wherein
the first color filter, the second color filter, and the third color filter are stacked one on another in the light-shielding area from a side of the insulating substrate toward a side of the display surface.

3. The display device of claim 1, wherein
the first color filter includes a first aperture at a position overlapping the third pixel aperture and a second aperture at a position overlapping the second pixel aperture,
the second color filter includes a third aperture at a position overlapping the third pixel aperture and a fourth aperture at a position overlapping the first pixel aperture, and
the third color filter includes a fifth aperture at a position overlapping the first pixel aperture and a sixth aperture at a position overlapping the second pixel aperture.

4. The display device of claim 1, further comprising:
an overcoat layer located between the sealing layer and the color filter layers,
wherein
the overcoat layer includes a groove portion overlapping the light-shielding area,
the first color filter, the second color filter, and the third color filter are stacked on top of each other at positions overlapping the groove portion, and
a part of the first color filter is located inside the groove portion.

5. The display device of claim 4, wherein
the groove portion surrounds each of the first pixel aperture, the second pixel aperture, and the third pixel aperture.

6. The display device of claim 1, wherein
the third pixel apertures of the pixels extend along the first direction,
the first pixel apertures are aligned along a second direction that intersects the first direction of the third pixel apertures; and
the second pixel apertures are aligned along the second direction of the third pixel apertures and aligned along the first direction of the first pixel apertures.
